(19) United States
(12) Patent Application Publication
(10) Pub. No.: US 2014/0169084 A1
(43) Pub. Date: Jun. 19, 2014

(54) Memory device

(71) Applicant: HITACHI, LTD., TOKYO (JP)

(72) Inventors: Joerg WUNDERLICH, Cambridgeshire (GB); Xavier MARTI, Praha 6 (CZ); Tomas JUNGWIRTH, Praha 6 (CZ)

(73) Assignee: HITACHI, LTD., TOKYO (JP)

(21) Appl. No.: 14/099,174

(22) Filed: Dec. 6, 2013

(30) Foreign Application Priority Data
Dec. 14, 2012 (EP) 12197333.3

(51) Int. Cl. H01L 43/02; G11C 11/16

(52) U.S. Cl. CPC H01L 43/02; G11C 11/161
USPC 365/158; 257/421

(57) ABSTRACT

A memory device is described. The memory device comprises an antiferromagnet. The device may comprise an insulator and an electrode arranged in a tunnel junction configuration. Alternatively, the device may comprise first and second contacts to the antiferromagnet for measuring ohmic resistance of the antiferromagnet. The antiferromagnet is not coupled to any ferromagnet. The state of the antiferromagnet can be set by heating the junction to a temperature at or above a critical temperature at which is possible to re-orientate magnetic moments in the antiferromagnet, applying an external magnetic field and then cooling the antiferromagnet to a temperature below the critical temperature.

### FIELD OF THE INVENTION

The present invention relates to a memory device. In particular, the present invention relates to an antiferromagnetic memory device.

### BACKGROUND

Magnetoresistive random-access memory (MRAM) is becoming increasingly used as solid-state non-volatile memory.

A typical MRAM cell includes two ferromagnetic layers separated by a thin, non-magnetic insulating layer which provides a tunnel barrier. One ferromagnetic layer, usually referred to as a “pinned layer” or “reference layer”, has a magnetization whose orientation is fixed. The other ferromagnetic layer, generally referred to as the “free layer”, has a magnetization whose orientation can be switched so as to be parallel or anti-parallel to the orientation of the magnetization in the pinned layer. Switching can be achieved by applying an external magnetic field or by passing a current having a sufficiently high current density in a process known as “spin torque transfer” (STT) switching. The parallel and anti-parallel states have high and low resistances respectively and, thus, can be used to store a bit of information. An overview of spin electronics, including MRAM, can be found in C. Chappert, A. Fert, and F. N. Van Dau: “The emergence of spin electronics in data storage” Nature Materials, volume 6, pages 813 to 823 (2007).

Another form of magnetoresistive device is a tunnelling anisotropy magnetoresistance (TAMR) device, as described in C. Gould et al.: “Tunneling Anisotropic Magnetoresistance: A Spin-Valve-Like Tunnel Magnetoresistance Using a Single Magnetic Layer”, Physical Review Letters, volume 93, page 117203 (2004). In a TAMR device, one of the ferromagnetic layers is replaced with a non-magnetic conductive layer. Magnetoresistance arises as a result of an anisotropy in local density of states at the interface between the tunnel barrier and the ferromagnetic layer.

As described in EP 2 065 886 A1, TAMR can be increased by including a thin layer of platinum or other transition metal between the non-magnetic insulating layer and the ferromagnetic layer.

B. G. Park et al.: “A spin-valve-like magnetoresistance of an antiferromagnet-based tunnel junction”, Nature Materials, volume 10, pages 347 to 351 (2011) describes another TAMR-like device having a multi-layer stack formed by a layer of nickel-iron (NiFe), a layer of iridium manganese (IrMn), a layer of magnesium oxide (MgO) and a layer of platinum (Pt). The MgO layer provides a tunnel barrier between antiferromagnetic IrMn and non-magnetic Pt. Ferromagnetic moments in the NiFe layer are reversed by an external magnetic field and the exchange-spring effect of NiFe on the IrMn layer induces rotation of the antiferromagnetic moments in IrMn layer.

The ferromagnetic NiFe layer is exchange-coupled to the antiferromagnetic IrMn layer to form an exchange spring. The ferromagnetic NiFe layer allows weak magnetic fields (i.e. of the order of the magnetic anisotropy fields in typical magnets) to rotate the antiferromagnetic moments. However, this arrangement limits the thickness of the IrMn layer to dimensions not exceeding the domain wall width in the antiferromagnet. Since the exchange spring triggers rotation of the antiferromagnetic moments at the opposite interface to the antiferromagnet/tunnel barrier interface, an antiferromagnetic TAMR effect is observable in antiferromagnetic films which are thinner than the domain wall width in the antiferromagnet.

Recent experiments have demonstrated that room-temperature antiferromagnetic TAMR can be realized in the exchange spring tunnel junctions in a narrow window of antiferromagnetic layer thicknesses. In such tunnel junctions, the antiferromagnetic layer should be thin enough to allow for the exchange spring rotation of antiferromagnetic moments across the entire width of the antiferromagnet, while being thick enough to avoid the suppression of the Néel temperature, T_{N}, below room temperature due to size effects.

### SUMMARY

According to a first aspect of the present invention there is provided a memory device comprising an antiferromagnet, an insulator and an electrode arranged in a tunnel junction configuration. The antiferromagnet is not coupled to any ferromagnet.

Thus, a ferromagnet can be omitted from the memory device and stray magnetic fields produced by the memory device can be minimised and may even be eliminated. Moreover, the antiferromagnet can store information more robustly such that it has greater resilience to magnetic field perturbation.

The antiferromagnet may be electrically conductive.

The antiferromagnet may comprise an alloy. The antiferromagnet may comprise a multilayer.

The antiferromagnet may comprise an alloy which includes and/or a multilayer which includes a layer of manganese (Mn).

The antiferromagnet may comprise an alloy which includes and/or a multilayer which includes a layer of a transition metal. The transition metal may be chromium (Cr), manganese (Mn), iron (Fe), cobalt (Co), nickel (Ni), copper (Cu), ruthenium (Ru), rhodium (Rh), palladium (Pd), gold (Ag), iridium (Ir), platinum (Pt) or silver (Au).

The antiferromagnet may comprise an alloy which includes a group 14 element, such as tin (Sn). The alloy may comprise up to 5% or up to 10% of the group 14 element. This can help to increase a transition temperature of the antiferromagnet.

The antiferromagnet may comprise an alloy which includes and/or a multilayer which includes a layer of a post-transition metal. The post-transition metal may be bismuth (Bi). The alloy may include manganese (Mn). For example, the alloy may comprise bismuth manganese (BiMn).

The antiferromagnet may comprise an oxide and/or a multilayer which includes a layer of an oxide. The oxide may be a transition metal oxide. The transition metal oxide may be chromium oxide (CrO), nickel oxide (NiO) or copper oxide (CuO).

The antiferromagnet may comprise a semiconductor and/or a multilayer which includes a layer of a semiconductor. The semiconductor may be a ternary alloy comprising a group 1 or group 11 element, a group 7 element and a group 15 element. The ternary alloy may be lithium manganese arsenide (LiMnAs), copper manganese arsenide (CuMnAs), copper manganese phosphide (CuMnP) or barium manganese arsenide (BaMn₂As₂).

The antiferromagnet may comprise a semimetal and/or a multilayer which includes a layer of a semimetal.

The antiferromagnet may take the form of layer, for example, a patterned layer. The antiferromagnet may have a thickness of at least 1 nm, at least 2 nm, at least 5 nm, at least 10 nm or more. The antiferromagnet may have a thickness no more than 10 nm, no more than 20 nm, no more than 50 nm, no more than 100 nm or more.

The memory device may comprise a non-ferromagnetic support and the antiferromagnet may be formed directly on the non-ferromagnetic support.

The non-ferromagnetic support may comprise at least one seed layer for providing an atomically-smooth surface directly supporting the antiferromagnet. The at least one seed layer may include a multi-layer stack comprising two or more layers of tantalum (Ta) and at least one layer of ruthenium (Ru) each ruthenium layer interposed between two tantalum layers.

The memory device may comprise a further electrode for providing electrical contact to the antiferromagnet. If present at least one seed layer is present, the at least one seed layer may be interposed between the antiferromagnet and the further electrode.

The memory device may further comprise a substrate supporting the antiferromagnet, insulator and electrode. The memory device may comprise a multilayer stack upstanding from the substrate.

The electrode may be non-ferromagnetic. The electrode may comprise a normal metal or a normal semiconductor. The electrode may comprise a transition metal, such as tantalum (Ta) or platinum (Pt). Using platinum or other transition metals can result in large changes in density of states and, thus, a greater magnetoresistance. The electrode may comprise an antiferromagnet. If the easy axes of the antiferromagnet and the electrode are different, then this can result in a greater magnetoresistance.

The electrode may be ferromagnetic. For example, the electrode may comprise cobalt or nickel iron alloy.

The memory device may further comprise a non-ferromagnetic layer interposed between the antiferromagnet and the insulator. The non-ferromagnetic layer may comprise a transition metal, such as platinum (Pt) or palladium (Pd). The non-ferromagnetic layer may be thin, for example, one or two monolayers thick.

The insulator may comprise an oxide, such as magnesium oxide. The insulator may be crystalline, for example, crystalline magnesium oxide.

The insulator may take the form of layer. The insulator may have a thickness of at least 0.5 nm, at least 1 nm, at least 2 nm or at least 5 nm. The insulator may have a thickness no more than 5 nm, no more than 10 nm.

The insulator may be antiferromagnetic. For example, insulator may comprise antiferromagnetic oxide of a transition metal, such as chromium or nickel.

According to a second aspect of the present invention there is provided apparatus comprising the memory device, a system or means for controlling temperature of the antiferromagnet and a system or means for applying a magnetic field to the antiferromagnet.

The temperature controlling means may comprise a cryostat or refrigerator. The temperature controlling system or means may comprise a thermoelectric cooler. The temperature controlling system or means may include a heater, such as a resistor or a laser. The memory device and the temperature controlling system or means may be supported on a single substrate, for example, in the form of integrally-formed temperature controller.

The magnetic field applying system or means may comprise a wire or coil. The magnetic field applying system or means may include a permanent magnet. The memory device and the temperature controlling means may be supported on a (or the) single substrate.

According to a third aspect of the present invention there is provided memory comprising an array of memory cells, each memory cell including the memory device, a temperature controller system and a set of magnetic field generators, each magnetic field generator configured to apply a magnetic field of first or second orientation to a respective memory device so as to configure the memory device in one of first and second metastable configurations.

The temperature controller system may comprise a thermoelectric cooler. The temperature controller system may include heater(s), such as resistor(s) or laser(s). The temperature controller system and the memory may be supported on a single substrate, i.e. an “on-chip” temperature controller system may be used.

Each magnetic field generator may comprise a set of one or more wires or coils. For example, a pair of wires (or coils) may be provided for each memory device. The magnetic field generators and memory cells may be supported on a single substrate, i.e. “on-chip” magnetic field generators may be used.

The magnetic field applying means may include a permanent magnet.

The temperature control elements, such as heaters, and magnetic field generators, e.g. conductive lines may be integrated into a unitary element. For example, a line having a weak link can be used not only to generate a magnetic field but also generate heat.

According to a fourth aspect of the present invention there is provided a method of configuring the memory device, the method comprising heating the antiferromagnet to a first temperature which is sufficiently high to allow magnetic moments in the antiferromagnet to be re-oriented, applying an external magnetic field to the antiferromagnet having re-orientable magnetic moments and cooling or allowing cooling (for example, by stopping heating) of the antiferromagnet to a second, lower temperature. The magnetic field can be applied while the antiferromagnet is being cooled or cooling or for part of the time that the antiferromagnet is being cooled or cooling. The magnetic field may be removed after the antiferromagnet is at the second temperature.

The first temperature may be at or above the Néel temperature of the antiferromagnet. Susceptibility tends to peak at the Néel temperature. However, the first temperature may be below the Néel temperature, provided that susceptibility is large enough for magnetic moments in the antiferromagnet to be re-orientated.

The second temperature is sufficiently low such that susceptibility is small enough to prevent magnetic moments in the antiferromagnet from being re-oriented.

The method may comprise applying a bias (e.g. a voltage bias or current bias) across the tunnel junction configuration so as to determine a tunneling anisotropic magnetoresistance.

According to a fifth aspect of the present invention there is provided a memory device and first and second contacts to the antiferromagnet for measuring ohmic resistance of the antiferromagnet. The antiferromagnet is not coupled to any ferromagnet.

Thus, a ferromagnet can be omitted from the memory device and stray magnetic fields produced by the memory device can be minimised and may even be eliminated. Moreover, the antiferromagnet can store information more robustly such that it has greater resilience to magnetic field perturbation.

The antiferromagnet may comprise an alloy which includes and/or a multilayer which includes a layer of a transition metal. The transition metal may be chromium (Cr), manganese (Mn), iron (Fe), cobalt (Co), nickel (Ni), copper (Cu), ruthenium (Ru), rhodium (Rh), palladium (Pd), gold (Ag), iridium (Ir), platinum (Pt) or silver (Au).

The antiferromagnet may comprise an alloy which includes a group 14 element, such as tin (Sn). The alloy may comprise up to 5% or up to 10% of the group 14 element. This can help to increase a transition temperature of the antiferromagnet.

The antiferromagnet may comprise an alloy which includes and/or a multilayer which includes a layer of a post-transition metal. The post-transition metal may be bismuth (Bi). The alloy may include manganese (Mn). For example, the alloy may comprise bismuth manganese (BiMn).

The antiferromagnet may comprise a semiconductor and/or a multilayer which includes a layer of a semiconductor. The semiconductor may be a ternary alloy comprising a group 1 or group 11 element, a group 7 element and a group 15 element. The ternary alloy may be lithium manganese arsenide (LiMnAs), copper manganese arsenide (CuMnAs), copper manganese phosphide (CuMnP) or barium manganese arsenide (BaMn₂As₂).

The antiferromagnet may comprise a semimetal and/or a multilayer which includes a layer of a semimetal.

The antiferromagnet may take the form of layer, for example, a patterned layer. The antiferromagnet may have a thickness of at least 1 nm, at least 2 nm, at least 5 nm, at least 10 nm or more. The antiferromagnet may have a thickness no more than 10 nm, no more than 20 nm, no more than 50 nm, no more than 100 nm or more.

The antiferromagnet may have an upper surface and the first and second contacts may be spaced apart and disposed on the upper surface.

The memory device may comprise a non-ferromagnetic support and the antiferromagnet may be formed directly on the non-ferromagnetic support.

The non-ferromagnetic support may comprise at least one seed layer for providing an atomically-smooth surface directly supporting the antiferromagnet. The at least one seed layer may include a multi-layer stack comprising two or more layers of tantalum (Ta) and at least one layer of ruthenium (Ru) each ruthenium layer interposed between two tantalum layers.

The memory device may further comprise a substrate supporting the antiferromagnet, insulator and electrode. The memory device may comprise a multilayer stack upstanding from the substrate.

The memory device may comprise third and fourth additional electrodes to the antiferromagnet for measuring four-terminal ohmic resistance of the antiferromagnet.

The, or each, electrode may be non-ferromagnetic. The, or each electrode, may comprise a normal metal or a normal semiconductor. The electrode may comprise a transition metal, such as tantalum (Ta) or platinum (Pt).

The memory device may further comprise a non-ferromagnetic layer interposed between the antiferromagnet and the insulator. The non-ferromagnetic layer may comprise a transition metal, such as platinum (Pt) or palladium (Pd). The non-ferromagnetic layer may be thin, for example, one or two monolayers thick.

The first and second electrodes may be directly in contact with the antiferromagnet.

The first and second electrodes may be disposed on a common surface (for example, an upper surface) of the antiferromagnet. The first and second electrodes may be embedded into (for example, diffused into) the antiferromagnet. The first and second electrodes may be disposed on side surfaces (on opposite sides) of the antiferromagnet.

There is preferably no tunnel barrier or at least no tunnel barrier which contributes significantly (e.g. more than 10%, more than 20% or more than 50%) to the device resistance between the first and second contacts. In other words, the memory device may use ohmic AMR readout and not TAMR readout.

The memory device may further comprise non-ferromagnetic layer(s) interposed between the first electrodes and the antiferromagnet and/or non-ferromagnetic layer(s) interposed between the first electrodes and the antiferromagnet. The layer(s) interposed between the first electrode and the antiferromagnet and the layer(s) interposed between the second electrode and the antiferromagnet may be the same.

According to a sixth aspect of the present invention there is provided apparatus comprising the memory device, means for controlling temperature of the antiferromagnet and means for applying a magnetic field to the antiferromagnet.

The temperature controlling means may comprise a cryostat or refrigerator. The temperature controlling means may comprise a thermoelectric cooler. The temperature controlling means may include a heater, such as a resistor or laser. The memory device and the temperature controlling means may be supported on a single substrate, for example, in the form of integrally-formed temperature controller.

The magnetic field applying means may comprise a wire or coil. The memory device and the temperature controlling means may be supported on a (or the) single substrate.

According to a seventh aspect of the present invention there is provided memory comprising an array of memory cells, each memory cell including the memory device, a temperature controller system and a set of magnetic field generators, each magnetic field generator configured to apply a magnetic field of first or second orientation to a respective memory device so as to configure the memory device in one of first and second metastable configurations.

The temperature controller system may comprise a thermoelectric cooler. The temperature controller system may include heater(s), such as resistor(s) or laser(s). The temperature controller system and the memory may be supported on a single substrate, i.e. an “on-chip” temperature controller system may be used.

Each magnetic field generator may comprise a set of one or more wires or coils. For example, a pair of wires (or coils) may be provided for each memory device. The magnetic field generators and memory cells may be supported on a single substrate, i.e. “on-chip” magnetic field generators may be used.

The temperature control elements, such as heaters, and magnetic field generators, e.g. conductive lines may be integrated into a unitary element. For example, a line having a weak link can be used not only to generate a magnetic field but also generate heat.

According to an eighth aspect of the present invention there is provided a method of configuring the memory device, the method comprising heating the antiferromagnet to a first temperature which is sufficiently high to allow magnetic moments in the antiferromagnet to be re-oriented, applying an external magnetic field to the antiferromagnet having re-orientable magnetic moments and cooling or allowing cooling (for example, by stopping heating) of the antiferromagnet to a second, lower temperature. The magnetic field can be applied while the antiferromagnet is being cooled or cooling or for part of the time that the antiferromagnet is being cooled or cooling. The magnetic field may be removed after the antiferromagnet is at the second temperature

The first temperature may be at or above the Néel temperature of the antiferromagnet. Susceptibility tends to peak at the Néel temperature. However, the first temperature may be below the Néel temperature, provided that susceptibility is large enough for magnetic moments in the antiferromagnet to be re-orientated.

The second temperature is sufficiently low such that susceptibility is small enough to prevent magnetic moments in the antiferromagnet from being re-oriented.

The method may comprise applying a bias (e.g. a voltage bias or current bias) between the first and second contacts so as to determine an ohmic anisotropic magnetoresistance.

According to a ninth aspect of the present invention there is provided a memory device comprising an antiferromagnet and at least one contact to the antiferromagnet. The antiferromagnet is not coupled to any ferromagnet.

### BRIEF DESCRIPTION OF THE DRAWINGS

Certain embodiments of the present invention will now be described, by way of example, with reference to the accompanying drawings in which:

FIG. 1 is a schematic diagram of a first multilayer structure including an antiferromagnetic layer which is not coupled to any ferromagnetic layer;

FIG. 2 schematically illustrates a first device formed from the multilayer structure shown in FIG. 1 which includes an antiferromagnet which is not coupled to any ferromagnet;

FIG. 3 schematically illustrates a disordered moment distribution state and first and second ordered moment distribution states corresponding to two different antiferromagnetic tunnel junction resistances;

FIG. 4 schematically illustrates apparatus for configuring and measuring the antiferromagnet shown in FIG. 2;

FIG. 5 is a process flow diagram of a method of configuring and measuring the antiferromagnet shown in FIG. 2;

FIG. 6 shows plots of tunnel resistance for field-cooling along positive and negative out-of-plane z-directions of a field and for in-plane x-direction and, in inset, a plot of stability of a state realized by field-cooling in an out-of-plane field;

FIG. 7 shows a plot of differential specific heat of a 2 nm IrMn sample indicating a Néel temperature of about 173 K and a plot of temperature dependence of tunnelling magnetoresistance corresponding to the relative difference between field-cool resistance measurements in 2T fields applied along out-of-plane (z) and in-plane (x) directions;

FIG. 8 schematically illustrates a memory including an array of memory cells;

FIG. 9 schematically illustrates a memory cell including an antiferromagnetic tunnel junction;

FIG. 10 is a schematic diagram of a second multilayer structure including an antiferromagnetic layer which is not coupled to any ferromagnetic layer;

FIG. 11 schematically illustrates a second device formed from the multilayer structure shown in FIG. 10 which includes an antiferromagnet which is not coupled to any ferromagnet;

FIG. 12 schematically illustrates first (high-resistance) and second (low-resistance) states;

FIG. 13 is a process flow diagram of a method of configuring and measuring the antiferromagnet shown in FIG. 11;

FIG. 14 schematically illustrates a memory including an array of memory cells; and

FIG. 15 schematically illustrates a memory cell.

### DETAILED DESCRIPTION OF CERTAIN EMBODIMENTS

### Antiferromagnetic Memory Device with TAMR Readout

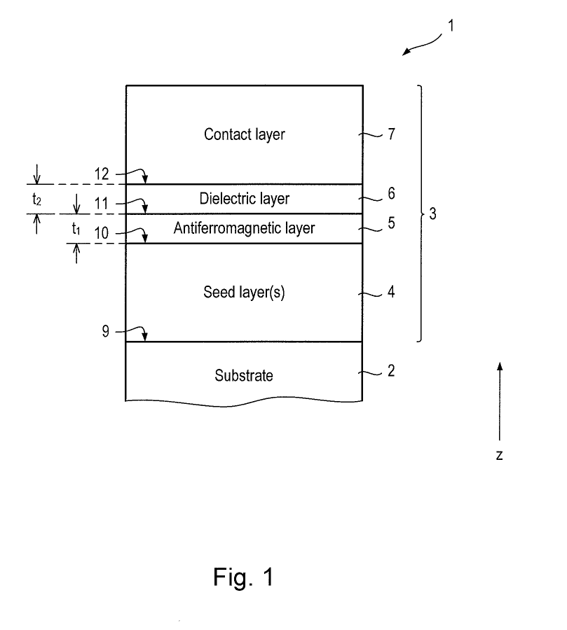

Referring to FIG. 1, a heterostructure 1 (herein also referred to as a “multilayer structure”) is shown. The multilayer structure 1 comprises a substrate 2 and a stack 3 of layers 4, 5, 6, 7 formed on the substrate 2. The substrate 2 can take the form of an oxidized silicon substrate, for example, 700 nm of silicon oxide (SiO₂) on (001) silicon.

The layer stack 3 is deposited under an ultrahigh vacuum by radio-frequency sputtering while a magnetic field of 5 mT is applied in an in-plane direction of the wafer 2.

A set of one or more seed layers 4 (or “buffer layers”) lies on an upper surface 9 of the substrate 2. In this example, the seed layers 4 include a first layer of tantalum (Ta), a layer of ruthenium (Ru) and a second layer of tantalum (Ta). The seed layers 4 can help to control texture, microstructure and morphology of an overlying layer 5. A layer 5 of antiferromagnetic material is formed on an upper surface 10 of the seed layers 4 and has a thickness t₁. The antiferromagnetic material comprises Ir_{0.2}Mn_{0.8} and different layer structures are formed having different values of thickness t₁ ranging from 2 to 8 nm, i.e. 2≦t₁≦8 nm. As will be explained in more detail later, the thickness of the antiferromagnetic material can be thicker than 8 nm, i.e. t₁≧8 nm. For example, the antiferromagnetic layer 5 can have a thickness of at least 10 nm, i.e. t₁≧10 nm. Some multilayer structures 1 are formed in which the antiferromagnetic layer 5 is thin, for example about 2 or 3 nm, so to decrease the Néel temperature of the material and so make it easier to go above and below the Néel temperature.

Other values of iridium content and manganese content can be used. Other antiferromagnetic materials can be used. For example, transition metals other than iridium can be used, such as chromium (Cr), iron (Fe), cobalt (Co), nickel (Ni) or palladium (Pd). An antiferromagnetic material alloy or an antiferromagnetic multilayer material can be used.

A layer 6 of dielectric material is formed on an upper surface 10 of the seed layers 4. The dielectric material is crystalline magnesium oxide (MgO). Magnesium oxide is deposited in amorphous form but is crystallised by annealing the multilayer structure 1 at 250° C. for 1 hour while a magnetic field of 0.4 T is applied along the flat-edge direction of the wafer after the layers 4, 5, 6, 7 have been deposited. The layer 6 has a thickness t₂ which is chosen to be sufficiently thin to form a tunnel barrier. In these examples, the layer 6 has a thickness of 2.5 nm, i.e. t₂=2.5 nm. However, the layer 6 can be thinner or thicker as required.

Other dielectric materials such as silicon dioxide (SiO₂), aluminium oxide (Al₂O₃) or high-k dielectrics such as hafnium oxide (HfO₂) can be used. The dielectric material may be antiferromagnetic.

The antiferromagnetic layer 5 is in direct contact with the dielectric layer 6 so that modifications of its relativistic spin-orbit coupled band structure at different antiferromagnetic configurations can yield a tunnelling anisotropic magnetoresistance (AFM TAMR).

A layer 7 of conductive material overlies an upper surface 12 of the dielectric layer 6. The conductive material is tantalum (Ta). However, other metals or a semiconductor material can be used.

The heterostructure 1 does not include a layer of ferromagnetic material, such as nickel iron (NiFe). Thus, the antiferromagnetic layer 5 is not coupled (via exchange coupling) to any ferromagnetic layer or region. Expressed differently, the antiferromagnetic layer 5 is ferromagnetically decoupled.

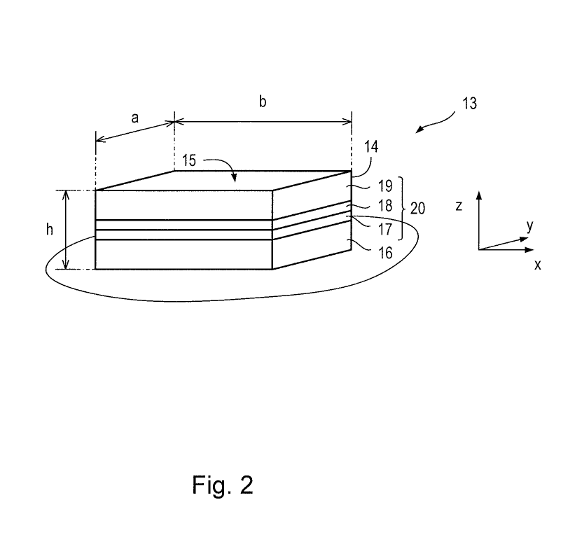

Referring also to FIG. 2, devices 13 can be formed by patterning the multilayer structure 1 to form pillar structures 14 or “mesas” (for clarity only one device and one pillar structure 14 is shown in FIG. 2) having an upper surface 15 and which includes a first contact 16, an antiferromagnet 17, a tunnel barrier 18 and a second contact 19 (which can be provided all or in part by the antiferromagnet 17). Suitable fabrication method steps are described in EP 2 065 886 A1.

The antiferromagnet 17, a tunnel barrier 18 and a second contact 19 form an antiferromagnetic tunnel junction 20 which can exhibit different metastable states corresponding to different spin configurations in the antiferromagnet 17.

At a temperature much lower than the Néel temperature, T_{N}, of the antiferromagnet 17, magnetic susceptibility χ of the antiferromagnet 17 is vanishingly small, i.e. zero. Thus, the antiferromagnet 17 is not polarized by the application of an external magnetic field. As temperature T increases and approaches the Néel temperature, magnetic susceptibility χ increases. At or above a temperature the Néel temperature, T_{N}, magnetic susceptibility χ tends towards infinity and the antiferromagnet 17 becomes paramagnetic. As temperature T is increased, anisotropy energy of magnetic moments in the antiferromagnet 17 decreases. Thus, at a sufficiently high temperature (but which is still below the Néel temperature, T_{N}), reorientation of magnetic moments in the antiferromagnet 17 becomes possible and an applied external magnetic field can induce a magnetization in the antiferromagnet 17. If the antiferromagnet 17 is cooled, then orientation of magnetic moments in the antiferromagnet 17 is frozen.

The state of an antiferromagnetic tunnel junction 20 can be set by cooling the junction 20 and crossing the Néel temperature by applying external magnetic fields having different orientations. These metastable states can be detected electrically using antiferromagnetic tunnelling anisotropic magnetoresistance (AFM TAMR). Using such a field-cooling approach, the need for an exchange spring can be avoided and so a ferromagnet need not be used. This allows thicker antiferromagnetic films to be used.

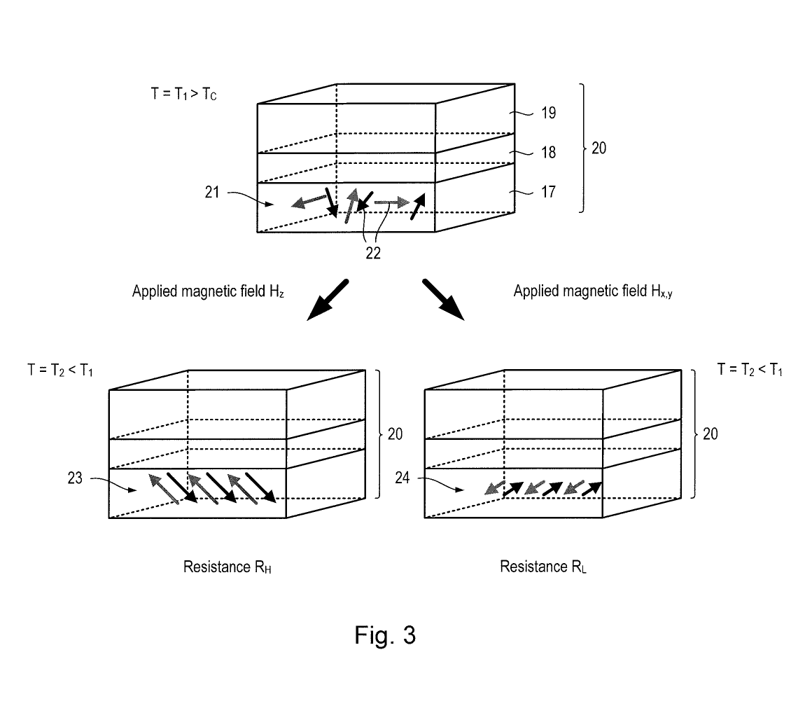

Referring also to FIG. 3, starting from a disordered state 21 of spins 22 at a temperature T₁ above a critical temperature T_{C} (which is usually the Néel temperature T_{N}) a lower resistance state R_{L} and a higher resistance state R_{H} of the antiferromagnetic tunnel junction 20 are obtained by cooling the device 13 in magnetic fields applied perpendicular or parallel to the upper surface 15 of the device 13. The enhanced susceptibility of the antiferromagnetic material when crossing the Néel temperature T_{N} allows realization of different metastable antiferromagnetic configurations 24, 25.

Transmission electron microscopy (TEM) images (not shown) shows that the heterostructure 1 has a high structural quality. Low- and high-resolution scanning transmission electron microscopy (STEM) images (not shown) show that stacking comprises continuous films over large distances. This is consistent with atomic force microscopy analysis at intermediate growth steps which revealed that each new layer preserved a root mean square (rms) roughness of less than 1 nm.

The TEM images confirm successful re-crystallization of magnesium oxide (MgO) after the annealing step carried out at 250° C. for 1 hour. The MgO dielectric layer 5 is highly textured along the out-of-plane [001] direction, parallel to the IrMn [111] texturation. This is also confirmed by X-ray diffraction measurements.

Pillar structures 14 are formed by photolithography and ion milling. The pillar structures 14 have a height, h. The height, h, is about 24 nm.

The pillars 14 are generally rectangular in cross section having sides a, b. Devices 13 having pillar structures 14 of different areas are formed. For example, one device has sides a=1 μm and b=2 μm. Another device has sides a=5 μm and b=10 μm. The pillars 14 can be circular in cross section.

The devices 13 show tunnelling I(V) characteristics and resistance-area products (RA) typical of standard MgO magnetic tunnelling junction with the same thickness.

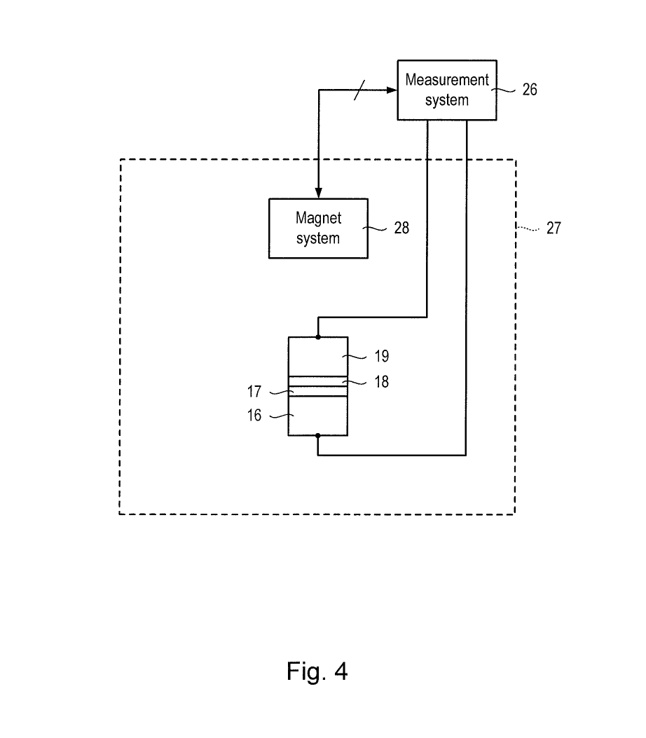

Referring to FIG. 4, a Quantum Design® Physical Property Measurement System (PPMS) 26 and an Oxford Instruments cryostat 27 furnished with vector magnet 28 is used to perform the magneto-transport measurements.

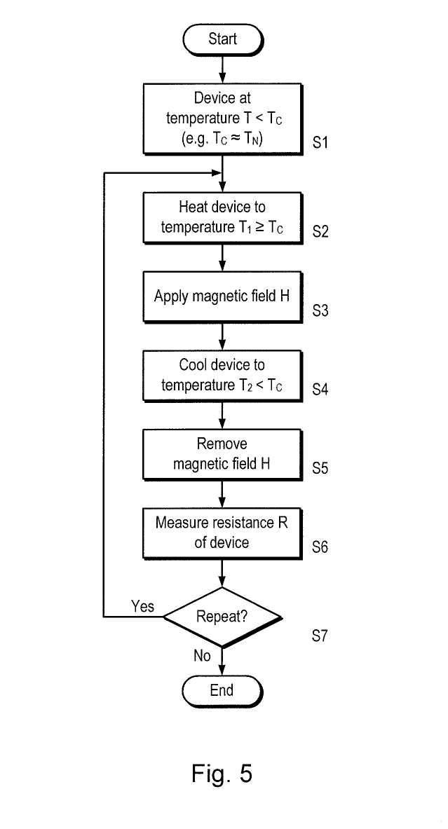

Referring also to FIG. 5, a device 13 is cooled or is at, for example, base temperature, T_{b}, of the cryostat (step S1). The device 13 is then warmed to temperature T₁ above a critical temperature T_{C} (step S2). The critical temperature T_{C} is typically the Néel temperature T_{N} of the antiferromagnet 17. However, in some cases, realignment of spins can occur at a temperature T slightly below the Néel temperature T_{N}. A magnetic field H is applied in a given direction (step S₃) and, while the magnetic field is still applied, the device 13 is cooled back to a temperature T₂ below critical temperature T_{C} so as to freeze the spins in given configuration (step S4). The resistance of the device 13 can be measured using TAMR.

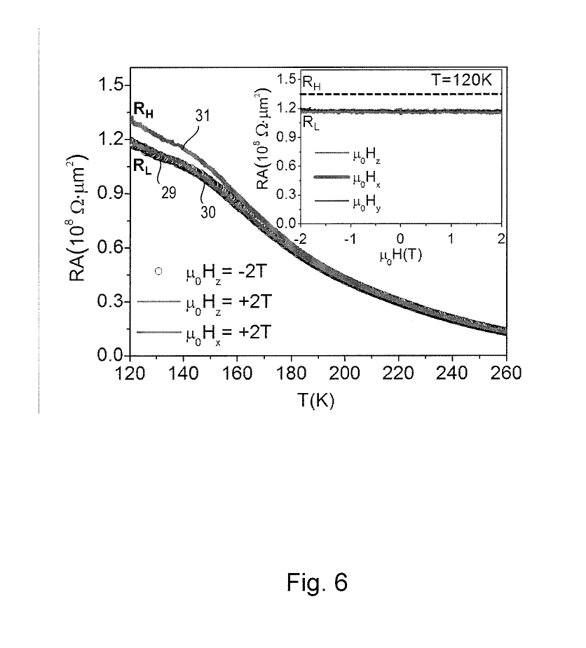

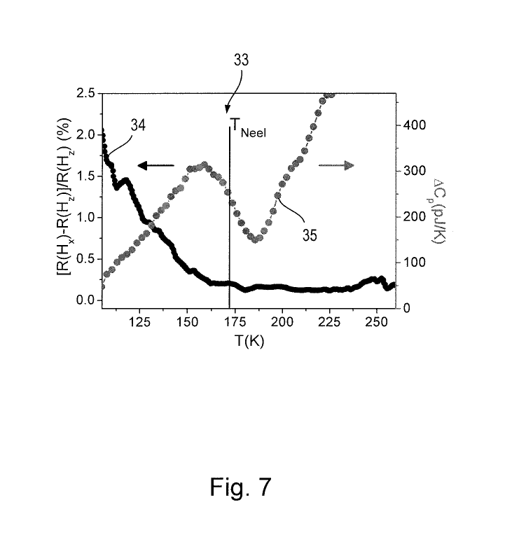

FIGS. 6 and 7 show experimental results for a device 13 (FIG. 2) having an antiferromagnet 17 (FIG. 2) formed from an Ir_{0.2}Mn_{0.8} antiferromagnetic layer 5 (FIG. 1) having a thickness of 2 nm, i.e. t₁=2 nm.

calorimetry measurements show that the Néel temperature T_{N} of the 2 nm-thick antiferromagnet 17 is to about 173 K. This makes it possible to perform field cooling from room temperature (about 290K) down to 120 K which covered a sufficiently large temperature range around the Néel temperature T_{N}.

In the main panel of FIG. 6, plots 29, 30 of RA product against temperature for external magnetic fields μ₀H_{z} of ±2T oriented perpendicular to the device surface are shown and a plot 31 of RA product against temperature for an external magnetic field μ₀Hₓ=+2T oriented in the plane of the sample along the [100] axis is shown.

The RA product is measured at a fixed bias of 20 mV and is identical for all three field orientations in the temperature interval from 300 K to approximately 170 K. However, below 170 K, the RA traces 29, 30 for out-of-plane magnetic field orientations and the RA trace 31 for in-plane magnetic field orientation split. At 120 K, the difference is more than 10%. As shown in the inset panel of FIG. 6, these states are metastable at temperatures sufficiently below T_{N}.

In the measurement, the higher resistance state was prepared by in-plane field cooling and then the temperature was stabilized at 120 K. The RA product (at 20 mV bias) was monitored while continuously sweeping the magnetic field in the out-of-plane direction (H_{z}) and also in the two orthogonal in-plane directions (Hₓ and H_{y}) between +2 T and −2 T, for 10 hours. No changes in the tunnelling resistance are observed within the experimental noise, which is much smaller than the difference between the higher and lower resistance states observed and shown in the main panel of FIG. 6. This demonstrates that a state prepared by field cooling is metastable and insensitive to relatively large external magnetic fields.

FIG. 7 illustrates that the field-cool magnetotransport effect shows signatures of an anisotropic magnetoresistance. In particular, while the temperature-dependent resistance traces for the in-plane and out-of-plane fields split below T_{N}, no difference is observed between field-cool measurements performed at fields with the opposite polarity. The observed magnetoresistance is not considered to be ascribed to magnetization-independent tunnelling transport phenomena due to, for example, Lorentz force effects of the magnetic fields applied along different directions with respect to the tunnelling current direction. These types of phenomena can be excluded since the field-cooling magnetoresistance disappears above the Néel temperature T_{N} and since a negligible magnetoresistance is observed when the temperature is stabilized below the Néel temperature T_{N} as shown in the inset of FIG. 6.

In FIG. 7, the onset 33 of the splitting of the RA traces for cooling in fields with different directions coincides with the transition in the 2 nm IrMn film to the ordered antiferromagnetic state.

FIG. 7 shows, side-by-side, a plot 34 of normalized variation of the tunnelling resistance (R(Hₓ)—R(H_{z}))/R(H_{z}) in a 2 nm IrMn pillar device 13 and a plot 35 of the differential specific heat of a 2 nm IrMn layer as a function of temperature. Quasi-adiabatic nanocalorimetry (QAnC) is a technique for investigating the Néel temperature of thin IrMn films. This technique allows for a direct measurement of the specific heat of a device, enabling the observation of the critical behaviour in the specific heat near the Néel temperature T_{N}. The Néel temperature inferred from the inflexion point of the specific heat singularity is approximately 173 K, i.e., it is significantly reduced in the 2 nm IrMn film as compared to the bulk IrMn where the Néel temperature T_{N}>1000 K. The reproducibility of the specific heat method was confirmed in different devices prepared in separate growth runs under the same growth conditions.

The correspondence between the Néel temperature T_{N} and the onset of the field-cool AFM TAMR has been confirmed by independent measurements using the PPMS and the vector magnet cryostat and studying different antiferromagnetic tunnel junctions with the same nominal layer structure. All the devices show a negligible magnetoresistance in the paramagnetic phase and a reproducible splitting of the RA traces when continuing the field-cooling below the Néel temperature T_{N} with in-plane and out-of-plane magnetic fields. The percentage difference between the two metastable resistance states obtained at 120 K varies from 2% to 10% in different antiferromagnetic tunnel junctions. The highest values were found in devices with the largest RA, consistent with the tunnelling origin of the observed phenomenon.

The microscopic mechanism which yields the field-cool TAMR in IrMn is distinct from high-field magnetotransport effects observed in iron pnictide antiferromagnetic tunnel junctions. In iron pnictide antiferromagnetic tunnel junctions, the magnetotransport effects have been ascribed to field-induced selection of structural crystal twin domains. IrMn does not undergo a crystal phase change near the Néel temperature. Therefore, it is possible to ascribe the distinct metastable states realized by field-cooling can be to distinct antiferromagnetic tunnel junctions configurations of a uniform IrMn film. Ir₂₀Mn₈₀ is believed to have two non-collinear antiferromagnetic phases 2Q and 3Q, confining magnetic spins in the plane or yielding an out-of-plane component respectively, with an energy difference of about 0.25 mRy/atom and a collinear phase whose energy is about 1.25 mRy/atom higher. Therefore, depending on the direction and strength of the applied field, the field-cooling procedure starting from temperatures above the Néel temperature T_{N} can favour spin configurations with different proportion of these distinct metastable antiferromagnetic phases.

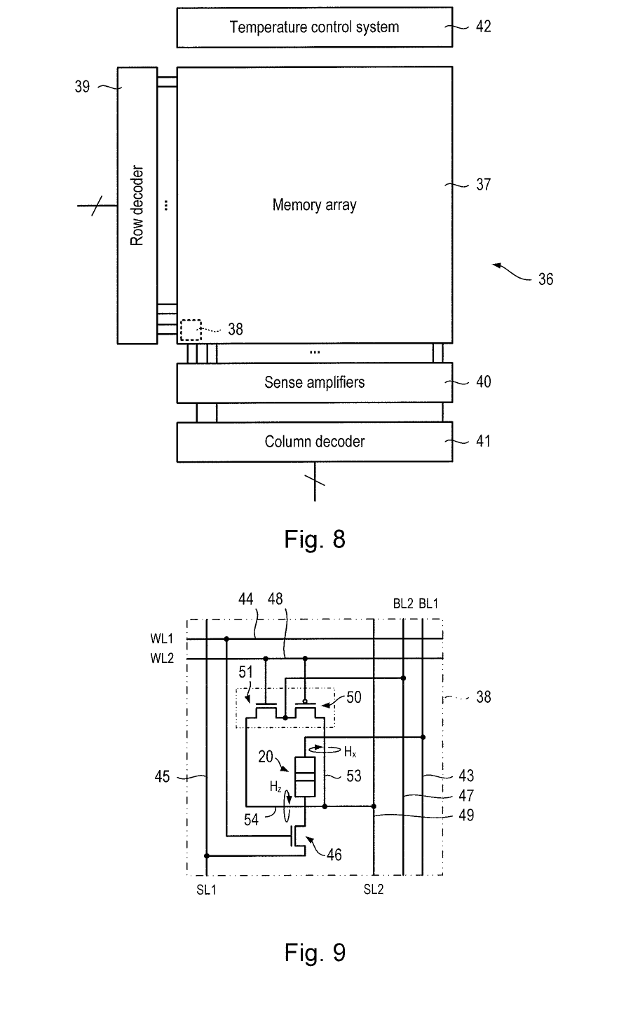

Referring to FIG. 8, a non-volatile memory 36 is shown. The memory 36 includes an array 37 of cells 38, a row decoder 39, sense amplifiers 40, a column decoder 41 and a temperature control system 42.

The temperature control system 42 can be configured to heat individual cells 38, several cells 38 and/or the whole array 37.

The temperature control system 42 can include resistors or other heat-generating elements (not shown).

Self-heating arrangements can be used. For example, a conductive line used to generate a magnetic field can include a weak link (i.e. a resistive section) which heats up when a current is passed through the line. Thus, the conductive line can be used not only to generate a magnetic field, but also to heat the antiferromagnet. Additionally or alternatively, internal heat generation arising from Joule heating when a current is passed through an antiferromagnetic tunnel junction can be used to heat the antiferromagnet.

The temperature control system 42 can include thermoelectric cooling devices (not shown).

Referring also to FIG. 9, a memory cell 38 is shown. The memory cell 38 includes an antiferromagnetic tunnel junction 20.

The memory cell 38 can be selected and the state of the cell 38 can be read using a first bit line 43, a first word line 44 and first select line 45 using a transistor 46 whose channel is arranged in series between the antiferromagnetic tunnel junction 20 and the select line 45 and which is controlled by the first word line 44.

The state of the cell 38 can be set using a second bit line 47, a second word line 48 and second select line 49 using a pair of transistor 50, 51 having non-inverting and inverting gates. Current through the bit line 47 can thus be selectively routed via first and second magnetic field generating lines 52, 53 which are orientated perpendicularly with respect to each other. The first magnetic field generating line 52 is used to generate a magnetic field perpendicular to the interfaces between the layers of the antiferromagnetic tunnel junction 20. The second magnetic field generating line 54 is used to generate a magnetic field parallel to the interfaces between the layers of the antiferromagnetic tunnel junction 20.

Antiferromagnetic Memory Device with Ohmic AMR Readout

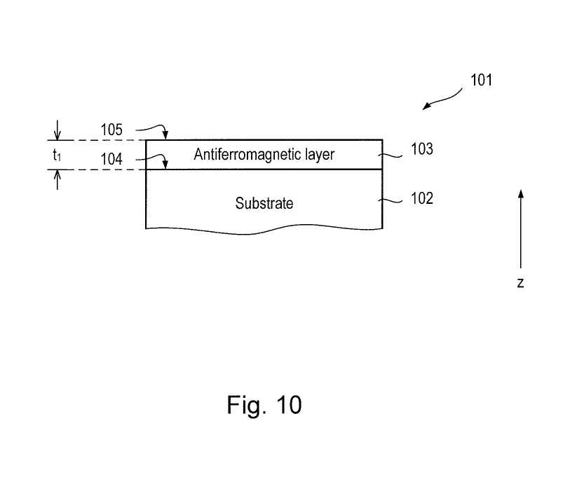

Referring to FIG. 10, a layer structure 101 is shown. The layer structure 101 comprises a substrate 102 and an antiferromagnetic layer 103 formed on an upper surface 104 of the substrate 102. The substrate 102 is electrically insulating. The substrate 102 can take the form of an oxidized silicon substrate, for example, 700 nm of silicon oxide (SiO₂) on (001) silicon.

The antiferromagnetic layer 103 is electrically conductive. The antiferromagnetic material in the antiferromagnetic layer 103 may be monocrystalline or polycrystalline. The antiferromagnetic material in the antiferromagnetic layer 103 may be a metal alloy or a semiconductor material. The antiferromagnetic layer 103 may be a layer of Ir_{0.2}Mn_{0.8}. The antiferromagnetic layer 103 has a thickness, t₁. The thickness, t₁, may have a value in a range from 2 to 8 nm, i.e. 2≦t₁≦8 nm. The thickness, t₁, can be thicker than 8 nm, i.e. t₁≧8 nm. For example, the antiferromagnetic layer 5 can have a thickness of at least 10 nm, i.e. t₁≧10 nm, of at least 20 nm, i.e. t₁≧20 nm, at least 50 nm, i.e. t₁≦50 nm, or at least 100 nm, i.e. t₁≦100 nm.

The antiferromagnetic layer 103 is deposited under an ultrahigh vacuum by radio-frequency sputtering. A magnetic field of 5 mT may be applied in an in-plane direction of the substrate 102 during deposition. Other methods of deposition, such as evaporation, atomic layer deposition and the like, may be used. The antiferromagnetic layer 103 has an upper surface 105.

The layer structure 101 does not include a layer of ferromagnetic material, such as nickel iron (NiFe). Thus, the antiferromagnetic layer 103 is not coupled (via exchange coupling) to any ferromagnetic layer or region. Expressed differently, the antiferromagnetic layer 103 is ferromagnetically decoupled.

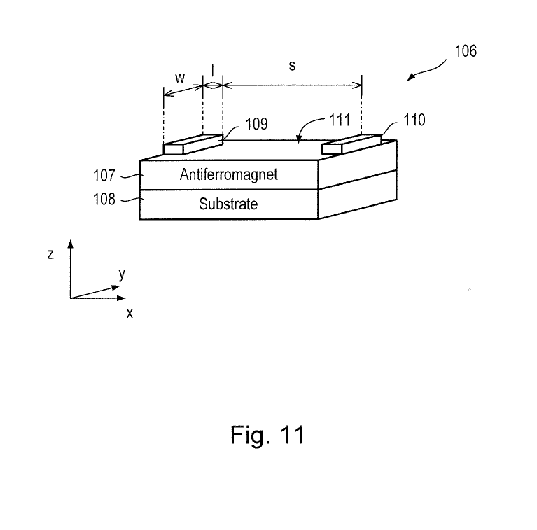

Referring also to FIG. 11, an antiferromagnetic device 106 can be formed by patterning the layer structure 101.

The device 106 comprises an antiferromagnet 107 (which may be provided by the unpatterned antiferromagnetic layer 103) supported by a non-ferromagnetic substrate 108 (which may be provided by the unpatterned substrate 102) and first and second contacts 109, 110 (or “electrodes”) in direct contact with the antiferromagnet 107. In this case, the contacts 109,110 are made on an upper surface 111 of the antiferromagnet 107. There is no tunnel barrier or at least no tunnel barrier which contributes significantly to resistance between the first and second contacts 109,110.

The contacts 109,110 are formed from metallic, non-ferromagnetic material. For example, the contacts 109, 110 may be formed of gold (Au).

The contacts 109,110 are spaced apart in a direction which defines a direction of current flow. The direction of current flow is labelled as the x-direction. If the antiferromagnetic material is monocrystalline, the x-direction may be aligned with a crystallographic direction.

The contacts 109, 110 have a separation, s. The separation, s, may be, for example, 1 μm. However, the separation, s, may be less than or more than 1 μm. The contacts 109,110 have a length, l, and width, w. The width, l, may be larger or smaller than the separation, s. The contacts 109, 110 and the antiferromagnet 107 are arranged so as to have a well-defined direction of current flow which includes a straight path section. For example, this may be achieved by having an antiferromagnetic layer which has a thickness, t₁, which is less than the contact separation, s, and the contact width, w.

The antiferromagnet 107 can exhibit different metastable states corresponding to different spin configurations in the antiferromagnet 107.

At a temperature much lower than the Néel temperature, T_{N}, of the antiferromagnet 107, magnetic susceptibility χ of the antiferromagnet 107 is vanishingly small, i.e. zero. Thus, the antiferromagnet 107 is not polarized by the application of an external magnetic field. As temperature T increases and approaches the Néel temperature, magnetic susceptibility χ increases. As temperature T is increased, anisotropy energy of magnetic moments in the antiferromagnet 107 decreases. Thus, at a sufficiently high temperature (which may be above or below the Néel temperature, T_{N}), reorientation of magnetic moments in the antiferromagnet 107 becomes possible and an applied external magnetic field can induce a magnetization in the antiferromagnet 107. If the antiferromagnet 107 is cooled, then orientation of magnetic moments in the antiferromagnet 107 is frozen.

The state of the antiferromagnet 107 can be set by applying by applying an external magnetic field at the transition temperature so as to align magnetic moments in the layer of antiferromagnetic material and, while the magnetic field is still being applied, field-cooling the layer and, once at a sufficiently low temperature, removing the external magnetic field. The state can be detected electrically using antiferromagnetic ohmic anisotropic magnetoresistance (AFM AMR).

Using such a field-cooling approach, the need for an exchange spring can be avoided and so a ferromagnet need not be used. This allows thicker antiferromagnetic films to be used.

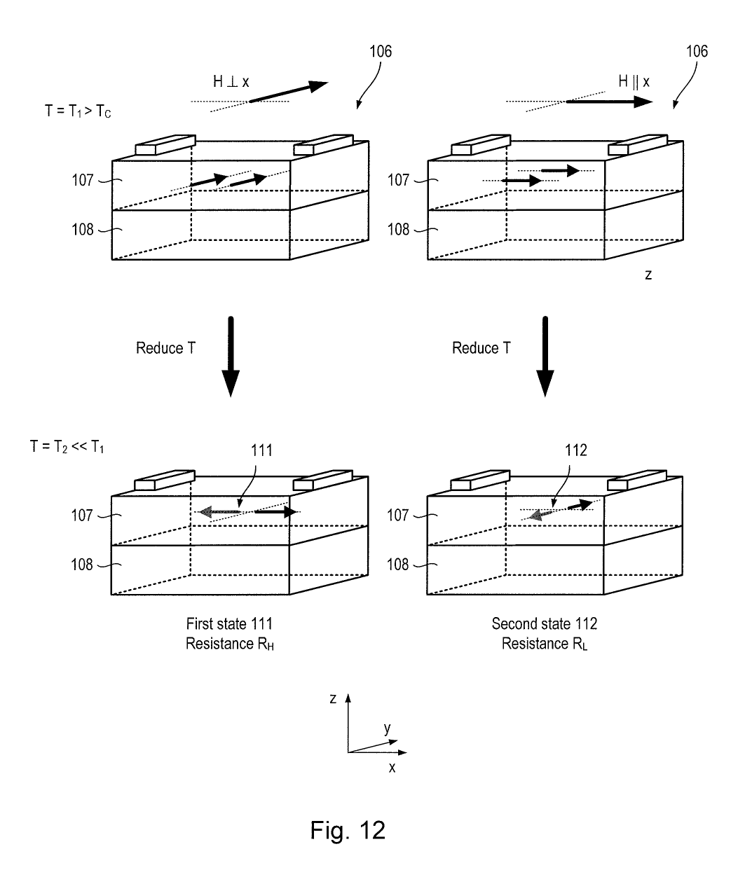

Referring also to FIG. 12, starting at a temperature T₁ at or above a critical temperature T_{C} (which can be the Néel temperature T_{N}), a first, high resistance state R_{H} and a second, low resistance state R_{H} of the antiferromagnet 107 are obtained by cooling the device 106 in magnetic fields applied along the x- or y-directions. The enhanced susceptibility of the antiferromagnetic material when crossing the Néel temperature T_{N} allows realization of different metastable antiferromagnetic configurations 111, 112.

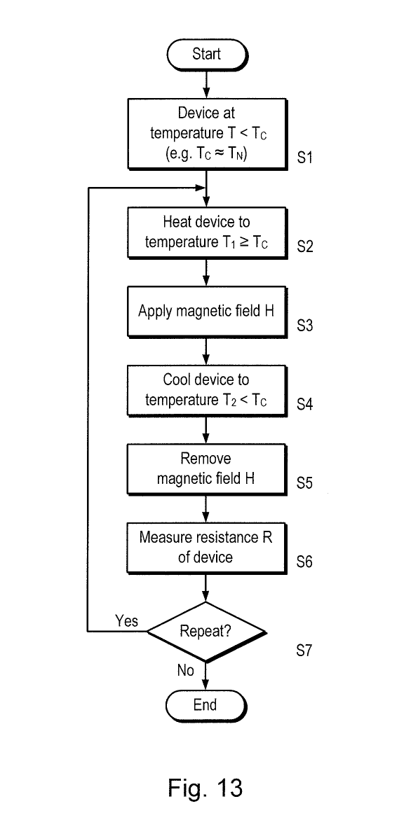

Magneto transport measurements of the antiferromagnetic device 106 can be performed using the measurement system and cryostat shown in FIG. 13.

Referring also to FIG. 13, a device 106 is cooled or is at, for example, base temperature, T_{b}, of the cryostat (step S1). The device 106 is then warmed to temperature T₁ which is at or about the critical temperature T_{C} (step S2). The critical temperature T_{C} is typically the Néel temperature T_{N} of the antiferromagnet 107. However, in some cases, realignment of spins can occur at a temperature T slightly below the Néel temperature T_{N}. A magnetic field H is applied in a given direction (step S3) and, while the magnetic field is still applied, the device 106 is cooled back to a temperature T₂ below critical temperature T_{C} (step S6). The resistance of the device 106 can be measured using AMR using a voltage or current source (not shown) which results in current flow between the contacts 109, 110. Orientation of magnetic moments in the antiferromagnet 107 with respect current flow determines the resistance state.

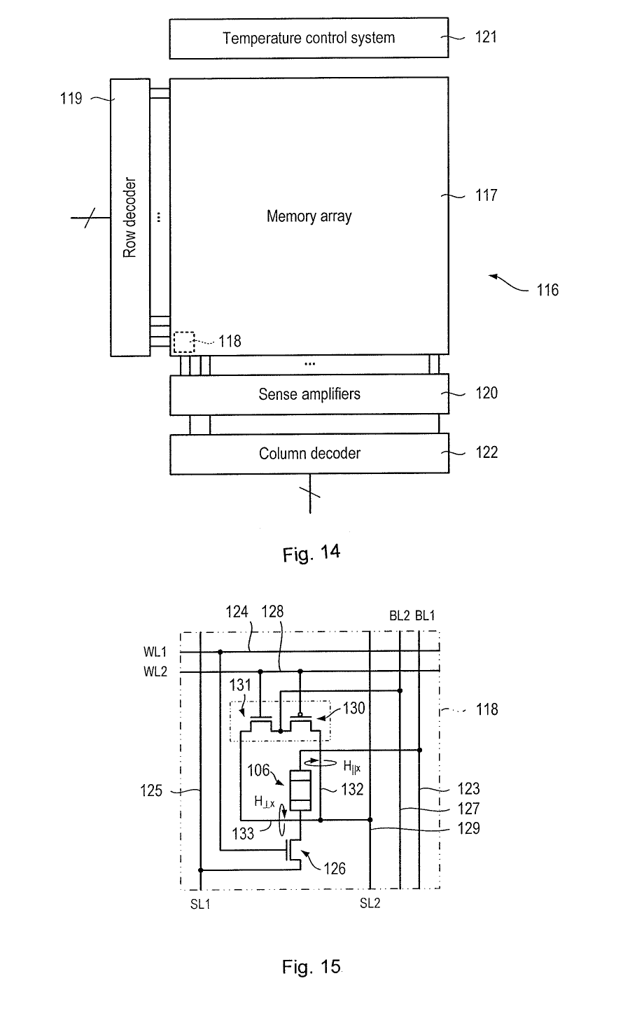

Referring to FIG. 14, a non-volatile memory 116 is shown. The memory 116 includes an array 117 of cells 118, a row decoder 119, sense amplifiers 120, a column decoder 121 and a temperature control system 122.

The temperature control system 122 can be configured to heat individual cells 118, several cells 118 and/or the whole array 117.

The temperature control system 121 can include resistors, laser or other heat-generating elements (not shown).

Self-heating arrangements can be used. For example, a conductive line used to generate a magnetic field can include a weak link (i.e. a resistive section) which heats up when a current is passed through the line. Thus, the conductive line can be used not only to generate a magnetic field, but also to heat the antiferromagnet. Additionally or alternatively, internal heat generation arising from Joule heating when a current is passed through an antiferromagnet can be used to heat the antiferromagnet.

The temperature control system 122 can include thermoelectric cooling devices (not shown).

Referring also to FIG. 15, a memory cell 118 is shown. The memory cell 118 includes an antiferromagnet ohmic resistor.

The memory cell 118 can be selected and the state of the cell 118 can be read using a first bit line 123, a first word line 124 and first select line 125 using a transistor 126 whose channel is arranged in series between the antiferromagnetic 106 and the select line 125 and which is controlled by the first word line 124.

The state of the cell 118 can be set using a second bit line 127, a second word line 128 and second select line 129 using a pair of transistor 130, 131 having non-inverting and inverting gates. Current through the bit line 127 can thus be selectively routed via first and second magnetic field generating lines 132, 133 which are orientated perpendicularly with respect to each other. The first magnetic field generating line 132 is used to generate a magnetic field parallel to the current path between the contacts 109, 110. The second magnetic field generating line 133 is used to generate a magnetic field perpendicular to the current path between the contacts 109, 110.

It will be appreciated that many modifications may be made to the embodiments hereinbefore described. Such modifications may involve equivalent and other features which are already known in the design, manufacture and use of memory device or parts thereof and which may be used instead of or in addition to features already described herein. Features of one embodiment may be replaced or supplemented by features of another embodiment.

The device can have different dimensions. For example, a thicker antiferromagnetic layer can be used. A top contact layer which is thicker or thinner can be used. The area of the antiferromagnetic layer can be different. Other materials, for example, other antiferromagnetic materials can be used. The antiferromagnetic layer may take the form of an alloy or a multilayer.

The antiferromagnetic tunnel junction can configured differently. For example, the antiferromagnetic tunnel junction need not take the form of a vertical device formed of a stack of coextensive layers. The antiferromagnetic tunnel junction may comprise overlapping layers of different areas. The device may include a planarising dielectric to contact the top of the device. A highly conductive contact pad, for example comprising gold, may be provided.

The ohmic antiferromagnetic configuration can be configured differently. For example, the antiferromagnet need not be planar. The antiferromagnet may be a vertical structure, for example a pillar, which is sufficiently narrow with respect to its height (i.e. having a sufficiently large aspect ratio) to define a current path.

Other different memory array arrangements and memory cell arrangements may be used.

The critical temperature, T_{C}, may exceed room temperature (i.e. about 293 K).

A cryostat or other cooling system may not be required.

T₂ may be room temperature. T₁ may be about 373 K or more.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A memory device comprising an antiferromagnet, an insulator and an electrode arranged in a tunnel junction configuration wherein the antiferromagnet is not coupled to a ferromagnet.

2. A memory device according to claim 1, further comprising a non-ferromagnetic support, wherein the antiferromagnet is formed directly on the non-ferromagnetic support.

3. A memory device according to claim 2, wherein the non-ferromagnetic support comprises at least one seed layer providing an atomically-smooth surface directly supporting the antiferromagnet.

4. A memory device according to claim 1, comprising an additional electrode for providing electrical contact to the antiferromagnet.

5. A memory device according to claim 1, further comprising a substrate supporting the antiferromagnet, insulator and electrode.

6. A memory device according to claim 1, wherein the electrode is non-ferromagnetic.

7. A memory device according to claim 6, wherein the electrode comprises an antiferromagnet.

8. A memory device according to claim 1, wherein the electrode (19) is ferromagnetic.

9. A memory device according to claim 1, further comprising a non-ferromagnetic layer interposed between the antiferromagnet and the insulator.

10. A memory device according to any preceding claim, wherein the insulator is antiferromagnetic.

11. Apparatus comprising:
a memory device according to claim 1;
a system for controlling temperature of the antiferromagnet; and
a system for applying a magnetic field to the antiferromagnet.

12. Memory comprising:
an array of memory cells, each memory cell including a memory device according to claim 1;
a temperature controller system; and
a set of magnetic field generators, each magnetic field generator configured to apply a magnetic field of first or second orientation to a respective memory device so as to configure the memory device in one of first and second metastable configurations.

13. A method of configuring a memory device according to claim 1, the method comprising:
heating the antiferromagnet to a first temperature which is sufficiently high to allow re-orientation of magnetic moments in the antiferromagnet;
applying an external magnetic field to the antiferromagnet while magnetic moments are re-orientable; and
cooling or allowing cooling of the antiferromagnet to a second, lower temperature.

14. A method according to claim 13, wherein the first temperature is at or above the Néel temperature of the antiferromagnet.

15. A method according to claim 13, wherein the second temperature is sufficiently low such that susceptibility is small enough to prevent magnetic moments in the antiferromagnet from being re-oriented.

16. A memory device comprising an antiferromagnet and first and second contacts to the antiferromagnet for measuring ohmic resistance of the antiferromagnet, wherein the antiferromagnet is not coupled to a ferromagnet.

17. A memory device according to claim 16, further comprising a non-ferromagnetic support, wherein the antiferromagnet is formed directly on the non-ferromagnetic support.

18. A memory device according to claim 17, wherein the non-ferromagnetic support comprises at least one seed layer providing an atomically-smooth surface directly supporting the antiferromagnet.

19. A memory device according to claim 16, further comprising third and fourth additional electrodes to the antiferromagnet for measuring four-terminal ohmic resistance of the antiferromagnet.

20. A memory device according to claim 16, further comprising a substrate supporting the antiferromagnet.

21. A memory device according to claim 16, wherein the first and second electrodes are directly in contact with the antiferromagnet.

22. A memory device according to claim 16, further comprising non-ferromagnetic layer(s) interposed between the first and second electrodes and the antiferromagnet.

23. Apparatus comprising:
a memory device according to claim 16;
a system for controlling temperature of the antiferromagnet; and
a system for applying a magnetic field to the antiferromagnet.

24. Memory comprising:
an array of memory cells, each memory cell including a memory device according to claim 16;
a temperature controller system; and
a set of magnetic field generators, each magnetic field generator configured to apply a magnetic field of first or second orientation to a respective memory device so as to configure the memory device in one of first and second metastable configurations.

25. A method of configuring a memory device according to claim 16, the method comprising:
heating the antiferromagnet to a first temperature which is sufficiently high to allow re-orientation of magnetic moments in the antiferromagnet;
applying an external magnetic field to the antiferromagnet while magnetic moments are re-orientable; and
cooling or allowing cooling of the antiferromagnet to a second, lower temperature.

26. A method according to claim 25, wherein the first temperature is at or above the Néel temperature of the antiferromagnet.

27. A method according to claim 25, wherein the second temperature is sufficiently low such that susceptibility is small enough to prevent magnetic moments in the antiferromagnet from being re-oriented.
